(19) United States
(12) Patent Application Publication
(10) Pub. No.: US 2024/0308729 A1
(43) Pub. Date: Sep. 19, 2024

(54) WIDE INSERTION ANGLE PROCESS CARRIER

(71) Applicant: ENTEGRIS, INC., Billerica, MA (US)

(72) Inventors: Lim Joo Chai, Kulim (MY); Michael C. Zabka, New Prague, MN (US)

(21) Appl. No.: 18/603,048

(22) Filed: Mar. 12, 2024

Related U.S. Application Data
(60) Provisional application No. 63/452,917, filed on Mar. 17, 2023.

(51) Int. Cl. B65D 25/10; B65D 1/36

(52) U.S. Cl. CPC B65D 25/107; B65D 1/36

(57) ABSTRACT

Process carriers include slots defined by teeth. The slots are each configured to receive a substrate, and each of the slots has slot angle in a range from 47° to 76°. The teeth can extend half or less of a height of the process carrier. The teeth can be configured to be spaced apart by at least a thickness of the disk or wafer to be received in the slots. The teeth can be configured such that when the substrate is seated in one of the plurality of slots, a center of the substrate is positioned towards a tooth end of the process carrier with respect to a height direction of the first side wall and the second side wall.

### PRIORITY CLAIM

This disclosure claims priority to and benefit of U.S. provisional patent No. 63/452,917 with a filing date of Mar. 17, 2023 which is incorporated by reference herein.

### FIELD

This disclosure is directed to process carriers for one or more substrates, specifically having a tooth profile providing a wide insertion angle for substrates.

### BACKGROUND

Process carriers can be used to store and carry substrates such as disks during processing. The substrates can be susceptible to contamination, such as by particles generated from the disks rubbing against parts of the process carrier.

### SUMMARY

This disclosure is directed to process carriers for one or more substrates, specifically having a tooth profile providing a wide insertion angle for substrates.

By reducing the length and increasing the insertion angle of the teeth used to define the slots in a process carrier, the amount of contact between the contained substrate and the process carrier can be reduced. The teeth are sized and shaped such that the tilt of disks is controlled within acceptable boundaries. This can reduce the generation of particulate from the process carrier, and improve process yield. The increased insertion angle can further allow use of the process carrier with a wider range of automation and reduce the required precision for automation handling the process carrier or the insertion or removal of substrates from said process carrier. The shape and position of the teeth can further be modified relative to the size of substrates to be contained so as to reduce the instances of disks becoming stuck within their respective slots.

In an embodiment, a process carrier includes a first side wall including a first plurality of teeth and a second side wall including a second plurality of teeth. The second side wall is opposite the first side wall. The first plurality of teeth and corresponding teeth of the second plurality of teeth define a plurality of slots. Each slot of the plurality of slots is configured to receive a substrate. Each of the slots have a slot angle in a range from 47° to 76°.

In an embodiment, the first plurality of teeth extends along a height direction of the first side wall by half or less of said height direction of the first side wall and the second plurality of teeth extends along a height direction of the second side wall by half or less of said height direction of the second side wall.

In an embodiment, the teeth of the first plurality of teeth are spaced apart by at least a thickness of the substrate and the teeth of the second plurality of teeth are spaced apart by at least a thickness of the substrate.

In an embodiment, the teeth of each of the first plurality of teeth and the second plurality of teeth each include a first side, a second side, and a tip between the first side and the second side.

In an embodiment, each of the slots have a slot angle in a range from 50° to 54°

In an embodiment, a process carrier includes a first side wall including a first plurality of teeth; and a second side wall including a second plurality of teeth. The second side wall is opposite the first side wall. The first plurality of teeth extends along a height direction of the first side wall by half or less of said height direction of the first side wall and the second plurality of teeth extends along a height direction of the second side wall by half or less of said height direction of the second side wall.

In an embodiment, the first plurality of teeth and corresponding teeth of the second plurality of teeth define a plurality of slots, each slot of the plurality of slots configured to receive a substrate. Each of the slots has a slot angle in a range from 47° to 76°. In an embodiment, each of the slots have a slot angle in a range from 50° to 54°

In an embodiment, the teeth of the first plurality of teeth are spaced apart by at least a thickness of the substrate and the teeth of the second plurality of teeth are spaced apart by at least a thickness of the substrate.

In an embodiment, the teeth of each of the first plurality of teeth and the second plurality of teeth each include a first side, a second side, and a tip between the first side and the second side.

In an embodiment, a method includes inserting a substrate into a slot configured to accommodate the substrate. The slot is defined in a process carrier. The process carrier includes a first side wall including a first plurality of teeth and a second side wall including a second plurality of teeth. The second side wall is opposite the first side wall. The first plurality of teeth and corresponding teeth of the second plurality of teeth define a plurality of slots. Each slot of the plurality of slots is configured to receive a substrate. Each of the slots has a slot angle in a range from 47° to 76°.

In an embodiment, the substrate is inserted into the slot using an automated substrate handler.

In an embodiment, the method further includes removing the substrate from the slot using an automated substrate handler.

In an embodiment, the first plurality of teeth extends along a height direction of the first side wall by half or less of said height direction of the first side wall and the second plurality of teeth extends along a height direction of the second side wall by half or less of said height direction of the second side wall.

In an embodiment, the teeth of the first plurality of teeth are spaced apart by at least a thickness of the substrate and the teeth of the second plurality of teeth are spaced apart by at least a thickness of the substrate.

In an embodiment, the teeth of each of the first plurality of teeth and the second plurality of teeth each include a first side, a second side, and a tip between the first side and the second side.

In an embodiment, when the substrate is seated in one of the plurality of slots, a center of the substrate is positioned towards a tooth end of the process carrier with respect to a height direction of the first side wall and the second side wall.

### DRAWINGS

FIG. 1 shows a process carrier according to an embodiment.

FIG. 2 shows a sectional view of the teeth of a process carrier according to an embodiment.

FIG. 3 shows a sectional view of a process carrier according to an embodiment and a wafer contained in said process carrier.

### DETAILED DESCRIPTION

This disclosure is directed to process carriers for one or more disks, specifically having a tooth profile providing a wide insertion angle for disks.

As used herein, “teeth” are defined as protrusions from an inner surface of a process carrier that are configured to support and/or retain substrates within the process carrier. Pluralities of teeth can be provided on each of two opposing inner surfaces of the process carrier. The teeth can be spaced apart by a gap.

As used herein, a “slot” is defined as a feature of the process carrier configured to accept one substrate. The slot can be defined by opposing side walls of each of a first pair of two adjacent teeth, and a corresponding second pair of two adjacent teeth provided on an opposing inner surface of the process carrier.

As used herein, a “slot angle” of a slot is the angle formed between the opposing side walls of each pair of adjacent teeth defining a slot. Where one or both of the opposing side walls include a curve, such as a concave or convex portion, the slot angle can be defined with respect to planes extending from a base of the tooth to the tip of the tooth for the respective side walls that include said curve.

As used herein, an “insertion angle” of a slot is a maximum deviation from the axis of the slot at which a substrate can still be successfully inserted into the slot. Where the opposing side walls defining the slot are mirror images of one another, the insertion angle can be one half of the slot angle.

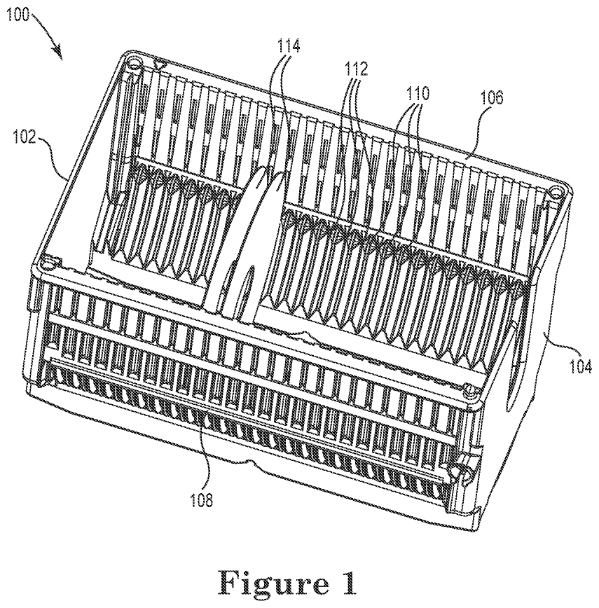

FIG. 1 shows a process carrier according to an embodiment. Process carrier 100 includes a first end wall 102, a second end wall 104, a first side wall 106, and a second side wall 108. Each of the first side wall 106 and second side wall 108 include a plurality of teeth 110. Teeth 110 are distributed across the first and second side walls 106, 108 so as to define slots 112. Corresponding slots 112 on the first side wall 106 and the second side wall 108 are aligned such that the corresponding slots 112 can each receive a substrate 114.

Process carrier 100 can be a process carrier configured to accommodate one or more substrates 114, for example during storage, transportation, and/or processing of those substrates 114. The process carrier 100 can be formed as a single piece or assembled from a plurality of component pieces. The process carrier 100 can be made of any suitable materials. For example, process carrier 100 can include polyether-ether-ketone (PEEK) material. In an embodiment, surfaces of the process carrier 100 contacting substrate 114 during use can be formed of the PEEK material. In an embodiment, the process carrier is composed entirely of the PEEK material.

First end wall 102 and second end wall 104 respectively define opposing ends of the process carrier 100. First side wall 106 extends from the first end wall 102 to the second end wall 104. The second side wall 108 also extends from the first end wall 102 to the second end wall 104. The first end wall 102, second end wall 104, first side wall 106, and second side wall 108 define a space capable of accommodating one or more disks 114.

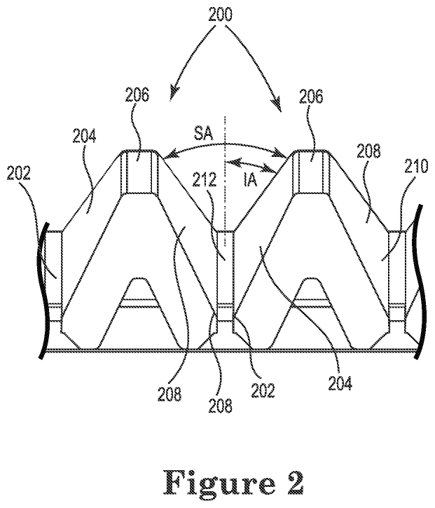

A plurality of teeth 110 extend from each of the first side wall 106 and second side wall 108 inwards into the internal space defined by the first end wall 102, second end wall 104, first side wall 106, and second side wall 108. The teeth can extend along a height direction of first side wall 106 and/or second side wall 108. The teeth 110 respectively distributed along the first side wall 106 and second side wall 108 can extend in the height direction of process carrier 100 by one half or less the height the height of said process carrier 100. The teeth 110 can be provided on a portion of first side wall 106 or second side wall 108 that is at or below half of the respective height of said first side wall 106 or second side wall 108. In an embodiment, each of teeth 110 extend outwards from the respective first or second side wall 106, 108 that said tooth 110 is disposed on by between 0.185±0.015 inches to 0.225±0.015 inches (0.470±0.038 cm to 0.572±0.038 cm). The portion of first side wall 106 and second side wall 108 where the teeth 110 extend from can be defined as a tooth end of the process carrier 100. Each of teeth 110 can include a first wall, a tip, and a second wall, for example the first side wall 204, tip 206, and second side wall 208 as described below and shown in FIG. 2. The first and second side walls can be straight or can be curved, for example having concavity or convexity when extending from the respective side wall 106 or 108 to the tip. The tip can be flat or rounded. In an embodiment, the tip is flat, with the transitions from the tip to the first and second walls each being rounded. In an embodiment, the teeth 110 are distributed along the first and second side walls 204, 206 such that the individual pitch of each of teeth 110 is 0.250±0.002 inches (0.635±0.005 cm) and the total pitch for the region containing the teeth 100 is 6.000±0.015 inches (15.240±0.038 cm) The opposing first and second walls of two adjacent teeth 110 form the opening of one of the slots 112.

Slots 112 are defined between adjacent teeth 110 along one of first side wall 106 or second side wall 108. Each pair of corresponding slots 112 on each of first side wall 106 and second side wall 108 can provide a support structure for one substrate 114. Slots 112 can be defined such that the adjacent teeth 110 forming said slot 112 are spaced apart by an amount equal to or greater than a thickness of a substrate 114 that the slot 112 is configured to accommodate. The slots 112 each have a slot angle in a range from 47° to 76°. The slot angle is an angle between opposing side walls of the teeth 110 defining the slot 112. Where the side walls include a curve, such as a concave or convex portion, the slot angle can be defined with respect to planes extending from a base of the tooth 110 to the tip of the tooth 110. In an embodiment, the slot angle is in a range from 50° to 54°. In an embodiment, the slots 112 each have an insertion angle of from 23.5° to 38°. The insertion angle is a maximum angle between a substrate 114 and the height direction of process carrier 100 at which the substrate 114 can be successfully inserted into the slot 112. In an embodiment, the insertion angle can be in a range from 25° to 27°. The insertion angle can be equal to one half of the slot angle, for example when the opposing side walls defining the slot 112 are mirror images of one another. The insertion angle for the slots 112 can allow for successful insertion even when there is misalignment of substrates, errors in the operation or positioning of automation handling such substrates, and the like. The insertion angles can allow use of the process carrier 100 with less precise automation for loading and unloading the substrates 114 from the process carrier 100. The slot and insertion angles of process carrier 100 can further reduce the risk of damage to substrates 114 and/or generation of particles from the process carrier 100 during loading and unloading. The slot angle and the insertion angle for the slots 112 of process carrier 100 can support successful insertion and seating of substrates 114 within slots 112 without requiring a lead-in portion on the teeth 110. Since a lead-in may not be required, the teeth 110 can be shorter along the height direction of process carrier 100, reducing the surface area of teeth 110 that can contact the substrates 114 and thus reducing the area where friction may occur between teeth 110 and the substrates 114. In an embodiment, the teeth 110 are distributed along the such that the individual pitch of each of teeth 110 is 0.250±0.002 inches (0.635±0.005 cm) and the total pitch for the region containing the teeth 100 is 6.000±0.015 inches (15.240±0.038 cm).

Substrate 114 can be, for example, a disk for use in a hard disk drive, a wafer, or any other suitable substrate to be contained in process carrier 100. The substrate 114 can be circular in shape. The process carrier 100 is configured to accommodate one or more of the substrates 114. The process carrier 100 is sized such that the one or more substrates 114 can be retained in the slots 112 defined by at least some of the teeth 110 provided along first side wall 106 and second side wall 108. The number of opposing slots 112 provided by the respective teeth 110 provided on first side wall 106 and second side wall 108 can correspond to the number of substrates 114 capable of being contained within the process carrier 100.

FIG. 2 shows a sectional view of the teeth of a process carrier according to an embodiment. Teeth 200 can be used as the teeth 110 provided in process carrier 100 as shown in FIG. 1 and described above. Each of the teeth 200 include a first side base 202, a first side wall 204, a tip 206, a second side wall 208, and a second side base 210. Adjacent teeth 200 are spaced apart by gap 212.

First side base 202 is where the tooth emerges from the side wall of the process carrier including said tooth 200 on a first side of said tooth. The first side base 202 can extend perpendicular to the surface of the side wall of the process carrier. First side wall 204 extends between first side base 202 and tip 206. In an embodiment, first side wall 204 extends straight from first side base 202 to tip 206. In embodiments, the first side wall 204 can have concavity or convexity as it extends from first side base 202 to tip 206.

Tip 206 forms the portion furthest from the wall of the process carrier that the tooth 200 is disposed on. Tip 206 divides the first and second sides of the tooth 200. Tip 206 can be flat or rounded. In an embodiment, tip 206 can have a height of between 0.185±0.015 inches to 0.225±0.015 inches (0.470±0.038 cm to 0.572±0.038 cm) away from the side wall of the process carrier that the tooth 200 is disposed on. The width of the tip 206 can be any suitable width to provide desired slot and insertion angles for the slots defined by adjacent teeth 200. In an embodiment, the width of the tip can be selected based at least in part on manufacturability, such as limitations on molding. In embodiments, the tip 206 can have a width in a range from 0.015 inches to 0.054 inches (0.038 cm to 0.137 cm). In embodiments, the width of the tip 206 can be selected relative to the width of the tooth from first side base 202 to second side base 210 such that the first and second side walls 204, 208 provide a slot angle SA in a range from 47° to 76° and an insertion angle IA of from 23.5° to 38°. Where the first side wall 204 and/or the second side wall 208 of adjacent teeth 200 define a slot include concavity or convexity, the insertion angle and/or the slot angle can be determined according to a straight line from first side base 202 to tip 206. In embodiments, the slots defined by first and second side walls 204, 208 of adjacent teeth 200 can define a slot angle SA in a range from 50° to 54° and an insertion angle IA in a range from 25° to 27°.

Second side wall 208 extends between tip 206 and second side base 210. In an embodiment, second side wall 208 extends straight from tip 206 to second side base 210. In embodiments, the first side wall 204 can have concavity or convexity as it extends from tip 206 to second side base 210. Second side base 210 is where the tooth emerges from the side wall of the process carrier including said tooth 200 on a second side of said tooth. The width of the tooth 200 can be defined by the distance from first side base 202 to second side base 210.

Gap 212 is a space between the respective bases 202, 210 of adjacent teeth 200 formed on a side wall of a process carrier, such first side wall 106 or second side wall 108 of process carrier 100 described above and shown in FIG. 1. The gap 212 can be sized such that the distance between the adjacent teeth 200 is equal to or greater than a thickness of the substrate that the teeth 200 are configured to receive, such as substrate 114 described above and shown in FIG. 1. The size of the gap 212 can be such that when the substrate seated the slot defined by the two adjacent teeth 200, a center of the substrate is positioned towards a tooth end of the process carrier with respect to a height direction of the first side wall and the second side wall. In an embodiment, the gap 212 can be 0.021±0.003 inches (0.053±0.0076 cm) in width.

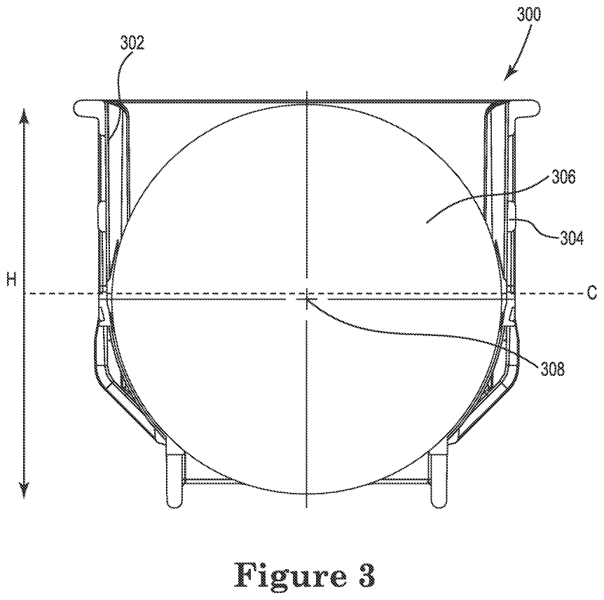

FIG. 3 shows a sectional view of a process carrier according to an embodiment and a substrate contained in said process carrier. Process carrier 300 includes first side wall 302 and second side wall 304. The process carrier 300 contains substrate 306. The substrate 306 is shown fully seated within the process carrier 300, being fully inserted into slots defined by teeth provided in process carrier 300 such as the teeth 110 defining a slot 112 as discussed above and shown in FIG. 1. The substrate 306 has a center point 308. When the substrate 302 is fully seated in the slots of process carrier 300, the center point 308 is positioned towards a tooth end of the process carrier with respect to a height direction of the first side wall and the second side wall. The center point 308 is at or below a center line C extending across process carrier 300 at half of the height H of process carrier 300. The seating of the substrate 306 such that center point 308 is below the center line can, for example, reduce the risk of the substrate 306 becoming stuck within process carrier 300. The process carrier 300 provides increased clearance for the widest portion of the substrate 306, and the teeth of process carrier also provide clearance for the portion of the profile of the substrate 306 at those teeth. The increased clearance can reduce the possibility of substrate 306 becoming clamped by the process carrier 300 and thus sticking within process carrier 300 during insertion or removal of the substrate 306.

Aspects:

It is understood that any of aspects 1-5 can be combined with any of aspects 6-10 or 11-17. It is understood that any of aspects 6-10 can be combined with any of aspects 11-17.

Aspect 1. A process carrier, comprising:
a first side wall including a first plurality of teeth; and
a second side wall including a second plurality of teeth, the second side wall opposite the first side wall;
wherein the first plurality of teeth and corresponding teeth of the second plurality of teeth define a plurality of slots, each slot of the plurality of slots configured to receive a substrate, each of the slots having a slot angle in a range from 47° to 76°.

Aspect 2. The process carrier according to aspect 1, wherein the first plurality of teeth extends along a height direction of the first side wall by half or less of said height direction of the first side wall and the second plurality of teeth extends along a height direction of the second side wall by half or less of said height direction of the second side wall.

Aspect 3. The process carrier according to any of aspects 1-2, wherein the teeth of the first plurality of teeth are spaced apart by at least a thickness of the substrate and the teeth of the second plurality of teeth are spaced apart by at least a thickness of the substrate.

Aspect 4. The process carrier according to any of aspects 1-3, wherein the teeth of each of the first plurality of teeth and the second plurality of teeth each include a first side, a second side, and a tip between the first side and the second side.

Aspect 5. The process carrier according to any of aspects 1-4, wherein each of the slots have a slot angle in a range from 50° to 54°

Aspect 6. A process carrier, comprising:
a first side wall including a first plurality of teeth; and
a second side wall including a second plurality of teeth, the second side wall opposite the first side wall;
wherein the first plurality of teeth extends along a height direction of the first side wall by half or less of said height direction of the first side wall and the second plurality of teeth extends along a height direction of the second side wall by half or less of said height direction of the second side wall.

Aspect 7. The process carrier according to aspect 6, wherein the first plurality of teeth and corresponding teeth of the second plurality of teeth define a plurality of slots, each slot of the plurality of slots configured to receive a substrate, each of the slots having a slot angle in a range from 47° to 76°.

Aspect 8. The process carrier according to aspect 7, wherein each of the slots have a slot angle in a range from 50° to 54°

Aspect 9. The process carrier according to any of aspects 6-8, wherein the teeth of the first plurality of teeth are spaced apart by at least a thickness of the substrate and the teeth of the second plurality of teeth are spaced apart by at least a thickness of the substrate.

Aspect 10. The process carrier according to any of aspects 6-9, wherein the teeth of each of the first plurality of teeth and the second plurality of teeth each include a first side, a second side, and a tip between the first side and the second side.

Aspect 11. A method comprising inserting a substrate into a slot configured to accommodate the substrate, wherein the slot is defined in a process carrier, the process carrier comprising:
a first side wall including a first plurality of teeth; and
a second side wall including a second plurality of teeth, the second side wall opposite the first side wall;
wherein the first plurality of teeth and corresponding teeth of the second plurality of teeth define a plurality of slots, each slot of the plurality of slots configured to receive a substrate, each of the slots having a slot angle in a range from 47° to 76°.

Aspect 12. The method according to aspect 11, wherein the substrate is inserted into the slot using an automated substrate handler.

Aspect 13. The method according to any of aspects 11-12, further comprising removing the substrate from the slot using an automated substrate handler.

Aspect 14. The method according to any of aspects 11-13, wherein the first plurality of teeth extends along a height direction of the first side wall by half or less of said height direction of the first side wall and the second plurality of teeth extends along a height direction of the second side wall by half or less of said height direction of the second side wall.

Aspect 15. The method according to any of aspects 11-14, wherein the teeth of the first plurality of teeth are spaced apart by at least a thickness of the substrate and the teeth of the second plurality of teeth are spaced apart by at least a thickness of the substrate.

Aspect 16. The method according to any of aspects 11-15, wherein the teeth of each of the first plurality of teeth and the second plurality of teeth each include a first side, a second side, and a tip between the first side and the second side.

Aspect 17. The method according to any of aspects 11-16, wherein when the substrate is seated in one of the plurality of slots, a center of the substrate is positioned towards a tooth end of the process carrier with respect to a height direction of the first side wall and the second side wall.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A process carrier, comprising:
a first side wall including a first plurality of teeth; and
a second side wall including a second plurality of teeth, the second side wall opposite the first side wall;
wherein the first plurality of teeth and corresponding teeth of the second plurality of teeth define a plurality of slots, each slot of the plurality of slots configured to receive a substrate, each of the slots having a slot angle in a range from 47° to 76°.

2. The process carrier of claim 1, wherein the first plurality of teeth extends along a height direction of the first side wall by half or less of said height direction of the first side wall and the second plurality of teeth extends along a height direction of the second side wall by half or less of said height direction of the second side wall.

3. The process carrier of claim 1, wherein the teeth of the first plurality of teeth are spaced apart by at least a thickness of the substrate and the teeth of the second plurality of teeth are spaced apart by at least a thickness of the substrate.

4. The process carrier of claim 1, wherein the teeth of each of the first plurality of teeth and the second plurality of teeth each include a first side, a second side, and a tip between the first side and the second side.

5. The process carrier of claim 1, wherein each of the slots have a slot angle in a range from 50° to 54°.

6. A process carrier, comprising:
a first side wall including a first plurality of teeth; and
a second side wall including a second plurality of teeth, the second side wall opposite the first side wall;
wherein the first plurality of teeth extends along a height direction of the first side wall by half or less of said height direction of the first side wall and the second plurality of teeth extends along a height direction of the second side wall by half or less of said height direction of the second side wall.

7. The process carrier of claim 6, wherein the first plurality of teeth and corresponding teeth of the second plurality of teeth define a plurality of slots, each slot of the plurality of slots configured to receive a substrate, each of the slots having a slot angle in a range from 47° to 76°.

8. The process carrier of claim 7, wherein each of the slots have a slot angle in a range from 50° to 54°.

9. The process carrier of claim 6, wherein the teeth of the first plurality of teeth are spaced apart by at least a thickness of the substrate and the teeth of the second plurality of teeth are spaced apart by at least a thickness of the substrate.

10. The process carrier of claim 6, wherein the teeth of each of the first plurality of teeth and the second plurality of teeth each include a first side, a second side, and a tip between the first side and the second side.

11. A method comprising inserting a substrate into a slot configured to accommodate the substrate, wherein the slot is defined in a process carrier, the process carrier comprising:
a first side wall including a first plurality of teeth; and
a second side wall including a second plurality of teeth, the second side wall opposite the first side wall;
wherein the first plurality of teeth and corresponding teeth of the second plurality of teeth define a plurality of slots, each slot of the plurality of slots configured to receive a substrate, each of the slots having a slot angle in a range from 47° to 76°.

12. The method of claim 11, wherein the substrate is inserted into the slot using an automated substrate handler.

13. The method of claim 11, further comprising removing the substrate from the slot using an automated substrate handler.

14. The method of claim 11, wherein the first plurality of teeth extends along a height direction of the first side wall by half or less of said height direction of the first side wall and the second plurality of teeth extends along a height direction of the second side wall by half or less of said height direction of the second side wall.

15. The method of claim 11, wherein the teeth of the first plurality of teeth are spaced apart by at least a thickness of the substrate and the teeth of the second plurality of teeth are spaced apart by at least a thickness of the substrate.

16. The method of claim 11, wherein the teeth of each of the first plurality of teeth and the second plurality of teeth each include a first side, a second side, and a tip between the first side and the second side.

17. The method of claim 11, wherein when the substrate is seated in one of the plurality of slots, a center of the substrate is positioned towards a tooth end of the process carrier with respect to a height direction of the first side wall and the second side wall.
